(19) United States
(12) Patent Application Publication
(10) Pub. No.: US 2003/0106210 A1
(43) Pub. Date: Jun. 12, 2003

(54) Chip-mounting device and method of alignment

(76) Inventors: Yoshiyuki Arai, Shiga (JP); Akira Yamauchi, Shiga (JP); Mikio Kawakami, Shiga (JP)

Correspondence Address: SMITH PATENT OFFICE, 1901 PENNSYLVANIA AVENUE N W, SUITE 200, WASHINGTON, DC, 20006

(21) Appl. No.: 10/275,908

(22) PCT Filed: May 21, 2001
(86) PCT No.: PCT/JP01/04224

(30) Foreign Application Priority Data
May 22, 2000 (JP) 2000-150339

(51) Int. Cl. H05K 3/30; B23P 19/00

(52) U.S. Cl. 29/833; 29/834; 29/739

(57) ABSTRACT

A chip-mounting device comprises a chip-holding tool and a substrate-holding stage. At least one of the chip-holding tool and the substrate-holding stage is placed on a coarse adjustment table for coarse positioning of a chip or a substrate. Brake means for fixing the positioned coarse adjustment table is provided on the coarse adjustment table. Fine adjustment means for fine positioning of a chip or a substrate is provided on the coarse adjustment table. The chip-mounting device allows alignment with submicorn accuracy to be performed quickly, shortening tact time in chip mounting remarkably.

### TECHNICAL FIELD OF THE INVENTION

The present invention relates to a chip-mounting device and a method of alignment in the chip-mounting device, and specifically to a chip-mounting device and a method of alignment in the device in which a desired alignment can be carried out with a high accuracy and quickly.

### BACKGROUND ART OF THE INVENTION

As known well, in a chip-mounting device, the position of a chip (for example, a semiconductor chip) held on a chip-holding tool and the position of a substrate (for example, a liquid crystal panel) held on a substrate-holding stage disposed below the chip-holding tool are positioned precisely, and in the positioned state, chip mounting is carried out by moving the chip-holding tool down.

For example, prior to the chip mounting, either the chip-holding tool or the substrate-holding stage is moved for coarse positioning between the chip and the substrate, and thereafter, for example, predetermined alignment marks provided on the chip and the substrate are recognized by recognition means, the precise positioning between the chip and the substrate is carried out so as to control the positional shift between both alignment marks within a range of a target accuracy by controlling the drive of the chip-holding tool or the substrate-holding stage.

In such a method, because the positional shift between both alignment marks is usually great in the state of the coarse positioning as described above, it is difficult to control the positional shift within a target accuracy by one alignment, and a plurality of alignments are necessary. The alignment is carried out such that a movable table to which a chip-holding tool or a substrate-holding stage is attached is driven, and the movable table is moved in an X-axis direction or a Y-axis direction or in both directions of X-axis and Y-axis (hereinafter, referred to as “parallel movement”) and rotated around a rotational axis, namely, the parallel movement and the rotation are carried out simultaneously, alternately or randomly (hereinafter, referred to as “concurrently”).

However, in such a alignment carrying out the parallel movement and the rotation concurrently, even if an error of the parallel movement has been controlled within a set range in a previous alignment, when a next rotational control is carried out, because there occurs a deflection of a rotational axis (a deflection of θ axis), the error of the parallel movement gets out from the range of the target accuracy again, and therefore, sometimes an accuracy higher than the error of the deflection of the axis cannot be achieved. Moreover, because the number of the repetition times of alignment increases in order to achieve the target accuracy, there is a problem that the tact time becomes long.

Further, a servo motor is frequently used as a drive source for controlling the position of the movable table, and in the control of such a servo motor, in order to control the rotational position of the servo motor to a target position, usually the servo motor is in a condition being always oscillated by ±one pulse. Therefore, the controlled position varies by an amount corresponding to this oscillation of ±one pulse, there occurs an unavoidable limit in positioning. accuracy, and in practice, positioning at submicron level is difficult.

### DISCLOSURE OF THE INVENTION

Accordingly, in consideration of the problems in the conventional devices and the accuracy limit in the conventional alignment as described above, an object of the present invention is to provide a chip-mounting device and a method of alignment in the device in which a high-accuracy alignment with submicron level can be surely carried out, and the high-accuracy alignment can be carried out quickly.

To accomplish the above object, a chip-mounting device according to the present invention has a chip-holding tool for holding a chip and a substrate-holding stage for holding a substrate on which the chip is to be mounted, the chip-mounting device comprises a coarse adjustment table for coarsely adjusting the position of a chip or a substrate, at least one of the chip-holding tool and the substrate-holding stage being placed on the coarse adjustment table; brake means provided on the coarse adjustment table for fixing the position of the coarse adjustment table after coarse adjustment; and fine adjustment means provided on the coarse adjustment table for finely adjusting the position of a chip or a substrate.

In the present invention, the “chip” includes all objects with forms being bonded to a substrate irrelevant to kind and size, such as an IC chip, a semiconductor chip, an optoelectronic element, surface mounting parts and a wafer. Further, the “substrate” includes all objects with forms being bonded to a chip irrelevant to kind and size, such as a resin substrate, a glass substrate, a film substrate, a chip and a wafer.

Although a table corresponding to a conventional movable table can be used as the above-described coarse adjustment table, in the present invention, the coarse adjustment table has brake means capable of fixing the position of the coarse adjustment table after coarse adjustment. This coarse adjustment table has relatively large control ranges of stroke and rotation similarly to those in a conventional movable table. On the other hand, the fine adjustment means finely adjusts the position so as to further approach the position to a target position after positioning by the coarse adjustment table, and therefore, it may have a small stroke. As such fine adjustment means, for example, means having a piezo element can be employed. By using a piezo element, a fine displacement (a fine expansion or a fine contraction) can be realized with a high accuracy in correspondence with applied voltage, and the position of the chip-holding tool or the substrate-holding stage can be adjusted finely and at a high accuracy by utilizing the fine displacement.

Further, for the above-described chip-mounting device, a linear scale (for example, a glass linear scale) can be used as means for detecting the adjusted position of a chip or a substrate. In order to realize a further high-accuracy alignment in consideration of the thermal deformation (thermal expansion or thermal shrinkage) of the linear scale, it is preferred that the linear scale is fixed at a predetermined reference position on its central portion in the longitudinal direction and the expansion of the linear scale is allowed in both directions from the reference position. In such a condition, for example, as compared with a case where the linear scale is fixed at its both ends, only the reference position, which is a target position for positioning or a near position, is fixed and a positional shift or a thermal deformation at a position near the reference position is suppressed to be extremely small, and therefore, a positional detection with a higher accuracy becomes possible. By adjusting the position of a chip or a substrate based on the feedback of the higher-accuracy positional detection, it becomes possible to control the position to a target position with a further high accuracy.

An alignment method in a chip-mounting device according to the present invention for recognizing an alignment mark provided on a chip held on a chip-holding tool and an alignment mark provided on a substrate held on a substrate-holding stage disposed below the chip-holding tool, by recognition means, and controlling the parallel movement. and the rotation of at least one of the chip-holding tool and the substrate-holding stage to control a positional shift between both the alignment marks within a target accuracy by correcting the positional shift, comprises the steps of coarsely adjusting the position of a chip or a substrate by driving at least one of the chip-holding tool and the substrate-holding stage by a coarse adjustment table; fixing the coarsely adjusted position of the coarse adjustment table; and finely adjusting the position of a chip or a substrate by driving at least one of the chip-holding tool and the substrate-holding stage by fine adjustment means. As the alignment mark recognition means, any type means may be employed, and for example, a two-sight camera can be used. As the recognition means in the present invention, any type may be employed irrelevant to kind and size as long as the means can recognize the alignment marks, for example, such as a CCD camera, an infrared camera, an X-ray camera and a sensor. Further, the recognition means is not limited to two-sight recognition means. For example, in a case where a chip and a substrate are suitable to transmission of a light including infrared, a method maybe suitable wherein one infrared camera is disposed above or below the chip and the substrate approached to each other, and a light source is provided at an opposite side (a coaxial illumination is also available) and the alignment marks are read in such a condition.

In the above-described chip-mounting device and method of alignment in the device according to the present invention, at first, the coarse positioning is carried out by the coarse adjustment table, and the coarsely adjusted position is fixed by the brake means. By this coarse positioning, schematic alignment to a position near the target-accuracy position can be achieved. This coarse positioning corresponds to a first alignment among alignment operations carried out repeatedly in a conventional method, and the time required for this alignment may be relatively short. After the coarse positioning, the coarsely adjusted position of the coarse adjustment table is fixed, and a fine positioning to a target control position is further carried out by the fine adjustment means provided on the coarse adjustment table. By fixing the coarsely adjusted position of the coarse adjustment table, for example, even in a case where a servo motor is used for driving the coarse adjustment table, the variation of the positional control ascribed to the oscillation of the servo motor corresponding to ±one pulse does not occur, and a variation factor in position to be controlled in the following fine adjustment also does not occur.

Since the fine adjustment means does not require a large stroke and it is constituted as means only for controlling a fine movement, a high-accuracy fine adjustment, which has not been achieved only by a conventional movable table, may be possible. Besides, because the fine adjustment is carried out at a condition where there is no variation factor in positional control as described above, the position may be adjusted to a target position to be controlled with a high accuracy only by one-time fine adjustment. Namely, in the present invention, positioning with an extremely high accuracy becomes possible by the two-stage control of substantially one-time coarse adjustment and one-time fine adjustment, alignment and chip mounting with submicron level (for example, 0.1 μm), which has not been achieved by a conventional method, becomes possible. Further, because only the two-stage control is required and it is not necessary to repeat alignment at many times as in the conventional method, the target accuracy can be achieved quickly, and the tact time can be greatly shortened.

Thus, in the present invention, since the fine adjustment is carried out by the fine adjustment means at a condition where the coarsely adjusted position achieved by the coarse adjustment table is fixed, the alignment between a chip and a substrate can be carried out with a high accuracy and quickly, positioning at submicron level, which has not been achieved by a conventional method, becomes possible, and the tact time in the chip mounting can be greatly shortened.

### BRIEF EXPLANATION OF THE DRAWINGS

FIG. 1 is a schematic perspective view of a chip-mounting device according to an embodiment of the present invention.

FIG. 2 is a perspective view of the chip-holding tool side of the device shown in FIG. 1, as viewed from an oblique lower direction.

FIG. 3 is a plan view of a portion of fine adjustment means of the device shown in FIG. 1, as viewed from an upper direction.

FIG. 4 is a perspective view of a case where linear scales are attached to a part of a coarse adjustment table of the device shown in FIG. 1.

### THE BEST MODE FOR CARRYING OUT THE INVENTION

Hereinafter, desirable embodiments of the present invention will be explained referring to figures.

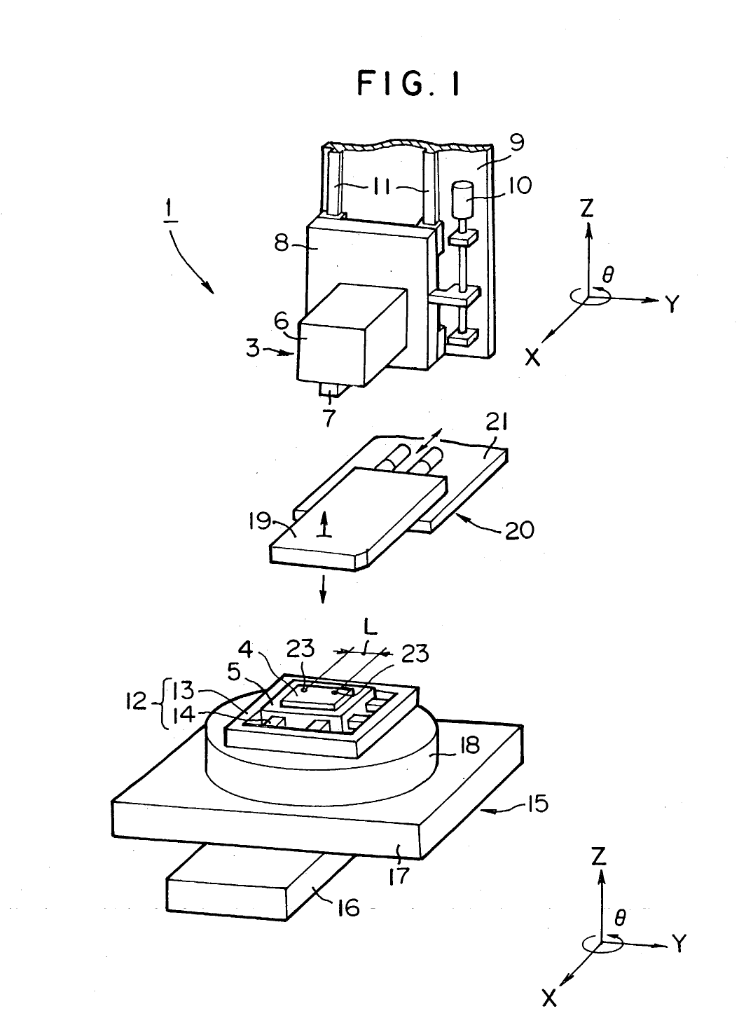

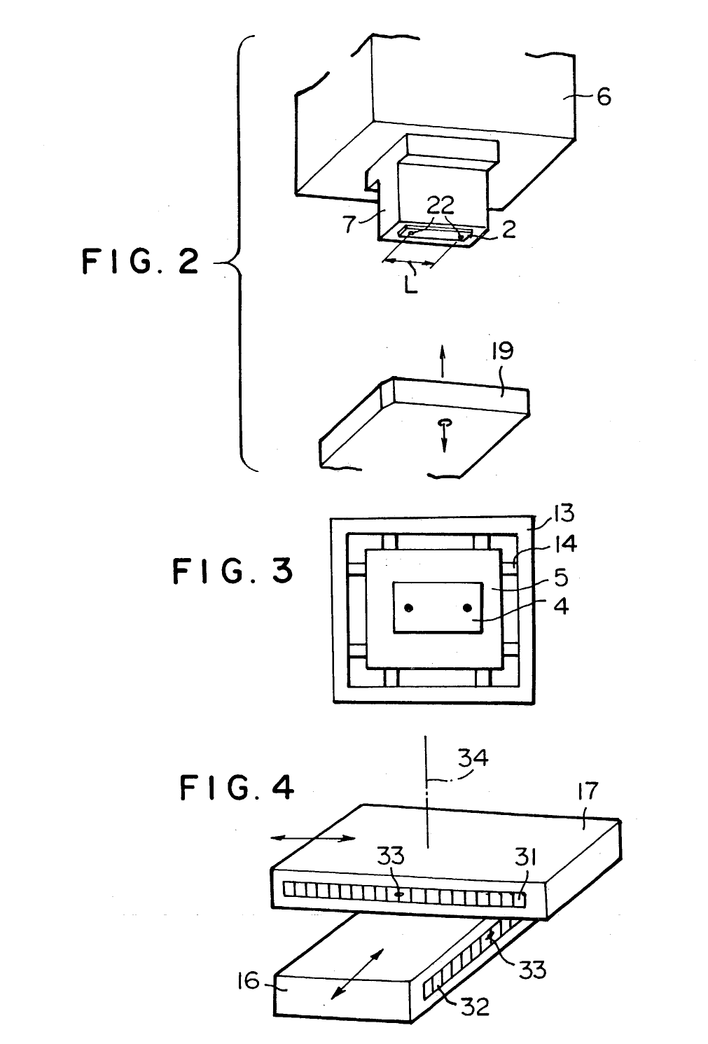

FIGS. 1-3 show a chip-mounting device according to an embodiment of the present invention. In FIGS. 1 and 2, chip-mounting device 1 has a head 3 for holding a chip 2 (for example, a semiconductor chip) by suction, etc. and a substrate-holding stage 5 disposed below the head 3 for holding a substrate 4 such as a circuit board or a liquid crystal panel by suction, etc. Head 3 has a block 6 and a chip-holding tool 7 provided on the lower end of the block 6 (hereinafter, also referred to as merely “tool”).

Head 3 is fixed to a movable table 8, and the movable table 8 is controlled to be moved up and down in the direction of Z axis along a pair of vertical rails 11 fixed to an upper frame 9 by drive control of a servo motor 10 attached to the upper frame 9. Positioning between chip 2 and substrate 4 can be carried out, for example, so that only the control of moving up and down is performed on chip 2 side, and parallel movement in the directions of X and Y axes and rotation (θ direction) around the rotational axis are controlled on substrate 4 side. Alternatively, parallel movement and rotation may be controlled on chip 2 side, and further, parallel movement and rotation may be controlled on both chip 2 side and substrate 4 side. In a case where the control function of the parallel movement in the directions of X and Y axes and/or the control function of the rotation in θ direction are given to chip 2 side in addition to the control function of the up and down movement, for example, the upper end of upper frame 9 may be attached to a movable table (not shown) in which parallel-movement control and/or rotational control are possible.

Substrate-holding stage 5 is held on fine adjustment means 12, the position of the substrate-holding stage 5 is finely adjusted by the fine adjustment means 12 together with substrate 4 held thereon. In this embodiment, fine adjustment means 12 is constructed as means having a fine adjustment table 13 and piezo elements 14 for finely driving the fine adjustment table 13. Piezo element 14 can finely control its expansion in correspondence with applied voltage. In this embodiment, also as shown in FIG. 3, for example, in fine adjustment table 13 two piezo elements 14 are disposed for each edge of the four edges of substrate-holding stage 5, and by controlling the applied voltage of each piezo element 14, the substrate-holding stage 5 and substrate 4 held thereon can be controlled for the parallel movement in the directions of X and Y axes relative to the fine adjustment table 13, and by the combination of drive amounts of the respective piezo elements 14, they can be controlled for the rotation in θ direction. Although two piezo elements 14 are disposed for each edge in this embodiment, except two elements, a single element or three or more elements may be disposed.

Fine adjustment table 13 of fine adjustment means 12 is provided on a coarse adjustment table 15. Coarse adjustment table 15 has an X-axis table 16 for controlling the movement in X-axis direction, a Y-axis table 17 for controlling the movement in Y-axis direction, and a rotational table 18 for controlling the rotation in θ direction. Further, it is preferred that coarse adjustment table 15 further has parallelism adjustment means (not shown) so that the parallelism between substrate-holding stage 6 and chip-holding tool 7 or the parallelism between substrate 4 and chip 2 can be adjusted by adjusting the inclination relative to Z-axis direction. The respective tables 16, 17 and 18 in coarse adjustment table 15 are driven by respective servo motors.

In this embodiment, recognition means 19 for recognizing alignment marks 22 and 23 in two directions of upper and lower directions is provided so as to be proceeded to and retreated from a position between head 3 and substrate-holding stage 5. Recognition means 19 is attached to a movable table 20 capable of being controlled for its parallel movement and vertical movement. Movable table 20 comprises a vertical-movement table (not shown) and a parallel-movement table 21 attached to the vertical-movement table.

Alignment mark 22 provided on chip 2 and alignment mark 23 provided on substrate 4 are detected, respectively, by recognition means 19. The pitch between a pair of alignment marks 22 provided on chip 2 and the pitch between a pair of alignment marks 23 provided on substrate 4 are the same pitch L. This pitch L is set at a size within each sight of recognition means 19. Based on the data of the respective alignment marks 22 and 23 detected by recognition means 19, positioning between chip 2 and substrate 4 is carried out.

In this embodiment, when positioning between chip 2 and substrate 4 is performed, especially the position of substrate 4 side is controlled. At that time, a linear scale, for example, a glass linear scale, can be used for the detection of adjusted position. For example, as shown in FIG. 4, the linear scale as detection means of adjusted position can be attached to coarse adjustment table 15, particularly, to X-axis table 16 and Y-axis table 17. Where, it is preferred that linear scales 31 and 32 are fixed at reference positions on the respective central portions in their longitudinal directions (fixed points 33), and the expansion (for example, thermal expansion and thermal shrinkage) of each linear scale is allowed in both directions from the reference position. This attachment reference points 33 are preferably set at positions corresponding to a center 34 of a reference position at which substrate 4 is to be held, and similarly, it is preferred that respective scale reading sensors (not shown) of linear scales 31 and 32 are provided at positions corresponding to the center 34. By such attachment of linear scales 31 and 32, as compared with a case where each linear scale is fixed at its both ends, even if there occurs a thermal deformation on linear scale 31 or 32, the deformation is performed at a condition where the reference point 33 is fixed at a predetermined position, and therefore, the influence given to the accuracy of the detected position ascribed to thermal deformation, etc. may be suppressed negligibly small, and a high-accuracy detection can be ensured.

In chip-mounting device 1 thus constructed, the alignment method according to the present invention is carried out as follows.

Alignment mark 22 of chip 2 held on head 3 and alignment mark 23 of substrate 4 held on substrate-holding stage 5 are read and the positions thereof are detected, respectively, by recognition means 19, and the positional shift therebetween is detected. The position of substrate-holding stage 5 side is adjusted and controlled so that this positional shift approaches zero, that is, desired positioning between chip 2 and substrate 4 is performed.

First, a target position to be controlled of substrate-holding stage 5 or substrate 4 is determined based on the above-described positional shift, and based on the target position, respective tables 16, 17 and 18 of coarse adjustment table 15 are controlled in parallel movement and rotation. In this coarse adjustment, the servo motors for driving the respective tables are pulse controlled to control the position to the target position, and from the control property of each servo motor, a variation corresponding to ±1 pulse occurs relative to the final target position.

In the present invention, after the above-described coarse adjustment, the coarsely adjusted position due to coarse adjustment table 15 is fixed by the brake means. An arbitrary known means may be employed as this brake means. For example, respective brake means may be provided to X-axis table 16, Y-axis table 17 and rotational table 18 to fix the respective tables, or merely the position of fine adjustment table 13 after the coarse adjustment may be fixed. Particularly, in this embodiment, because fine adjustment means 12 for finely adjusting the position of substrate-holding stage 5 relative to fine adjustment table 13 by piezo elements 14 is used, at first the position of the fine adjustment table 13 may be fixed at the coarsely adjusted position.

As to the above-described fixing of the coarsely adjusted position by the brake means, the following control method can be employed. Although an integral control is performed for usual positional control using a servo motor, because the aforementioned oscillation of ±1 pulse is always occurring in a condition where the integral control is being continued, the control may be once changed to a proportional control and then braking may be carried out. Alternatively, a method may be employed wherein a servo motor is completely turned to be off after the coarse adjustment and in this state braking is carried out.

A precise fine adjustment carried out by fine adjustment means 12 is performed after fixing the coarsely adjusted position. Appropriate voltages are applied to respective piezo elements 14 arranged as shown in FIG. 3, and the position of substrate-holding stage 5, ultimately, the position of substrate 4 held thereon, is finely adjusted by the operation of expansion/contraction of each piezo element 14.

In this fine adjustment, since the coarse adjustment has been already carried out in the prior stage, the adjustment may be performed by a small stroke, and because an extremely high-accuracy fine adjustment means is constituted by using piezo elements 14, an extremely high-accuracy positioning becomes possible by one-time fine adjustment. Moreover, since this fine adjustment is performed at a condition of the already controlled, coarsely adjusted position and in the coarsely adjusted position a variation factor ascribed to ±1 pulse oscillation of a servo motor is removed by fixing the position, it is possible to control the positioning with a further high accuracy. As a result, only by one coarse adjustment and one fine adjustment, a high-accuracy positioning with submicron level (for example, 0.1 μm), which has not been achieved by a conventional movable table, becomes possible, and the accuracy for the positioning is increased remarkably.

Further, because the number of the times of adjustment may be small, as compared with a conventional method for repeating adjustment many times, the control time for reaching a target position can be greatly shortened together with achievement of the high-accuracy positioning, and therefore, the tact time in the chip mounting can be shortened remarkably.

Although fine adjustment means 12 is provided only to the adjustment side of substrate 4 in the above-described embodiment, it is possible to provide it to the adjustment side of chip 2, and it is possible to provide it to both sides. Further, as to the alignment marks provided on chip 2 and substrate 4, any type alignment marks, such as printed marks, may be used.

Industrial Applications of the Invention

The present invention can be applied to any type of chip-mounting device and alignment in the device, and a high-accuracy positioning and a great reduction of tact time can be both achieved. Therefore, a quality of a mounted product and a productivity can be both increased.

1. A chip-mounting device having a chip-holding tool for holding a chip and a substrate-holding stage for holding a substrate on which said chip is to be mounted, the chip-mounting device comprising:
a coarse adjustment table for coarsely adjusting the position of a chip or a substrate, at least one of said chip-holding tool and said substrate-holding stage being placed on said coarse adjustment table;
brake means provided on said coarse adjustment table for fixing the position of said coarse adjustment table after coarse adjustment; and
fine adjustment means provided on said coarse adjustment table for finely adjusting the position of a chip or a substrate.

2. The chip-mounting device according to claim 1, wherein said fine adjustment means includes a piezo element.

3. The chip-mounting device according to claim 1, wherein a linear scale is provided as means for detecting the adjusted position of a chip or a substrate, said linear scale is fixed at a predetermined reference position on its central portion in the longitudinal direction, and the expansion of said linear scale is allowed in both directions from said reference position.

4. An alignment method in a chip-mounting device for recognizing an alignment mark provided on a chip held on a chip-holding tool and an alignment mark provided on a substrate held on a substrate-holding stage disposed below said chip-holding tool, by recognition means, and controlling the parallel movement and the rotation of at least one of said chip-holding tool and said substrate-holding stage to control a positional shift between both said alignment marks within a target accuracy by correcting the positional shift, comprising the steps of:
coarsely adjusting the position of a chip or a substrate by driving at least one of said chip-holding tool and said substrate-holding stage by a coarse adjustment table;
fixing the coarsely adjusted position of said coarse adjustment table; and
finely adjusting the position of a chip or a substrate by driving at least one of said chip-holding tool and said substrate-holding stage by fine adjustment means.

5. The alignment method in a chip-mounting device according to claim 4, wherein a camera is used as said recognition means for recognizing said alignment marks.
